(19) United States
(12) Patent Application Publication
(10) Pub. No.: US 2025/0171896 A1
(43) Pub. Date: May 29, 2025

(54) APPARATUS FOR FINE POWDER PARTICLE PROCESSING UTILIZING CENTRIFUGAL CONFINEMENT TO MITIGATE PARTICLE ELUTRIATION

(71) Applicant: CVD Equipment Corporation, Central Islip, NY (US)

(72) Inventors: Samuel J. Wright, Bellport, NY (US); Maxim S. Shatalov, Mt. Sinai, NY (US); Emmananuel Lakios, Mt. Sinai, NY (US); Paul J. Decker, Ridge, NY (US); John B. Feraca, Shirley, NY (US)

(21) Appl. No.: 18/840,629

(22) PCT Filed: Feb. 23, 2023
(86) PCT No.: PCT/US2023/013691

§ 371 Date: Aug. 22, 2024

Related U.S. Application Data
(60) Provisional application No. 63/312,851, filed on Feb. 23, 2022.

(51) Int. Cl. C23C 16/44; B01J 8/08; B01J 8/10; C23C 16/52

(52) U.S. Cl. CPC C23C 16/4417; B01J 8/085; B01J 8/10; C23C 16/52

(57) ABSTRACT

A powder treatment system with variable speed of rotation of a treatment vessel containing the powder at different stages of the treatment process. During treatment stages where gas flow may be present (e.g., pump down), the treatment vessel is spun at a centrifugal speed in order to confine the fine powder particles within the treatment vessel and prevent or substantially minimize elutriation losses. During treatment stages where gas flow may be minimal or not present (e.g., treatment dwell time), the rotational speed of the treatment vessel is a cataracting speed in order to uniformly treat the fine powder particles whilst avoiding or substantially minimizing elutriation losses. A movable comb can be moved from a first position not in contact with the particles confined against the inner surface of the treatment vessel during rotation of the treatment vessel at a centrifugal speed, to a second position that encourages separation of the particles from the inner surface of the treatment vessel and breaks up agglomerates during rotation of the treatment vessel at a cataracting speed.

### CROSS-REFERENCE TO RELATED APPLICATIONS

This application claims the benefit of, and priority to, U.S. Provisional Patent Application No. 63/312,851 filed on Feb. 23, 2022, the entire contents of which are hereby incorporated herein by reference.

### BACKGROUND

Powder processing is typically done in either a fluidized bed reactor or a rotary drum reactor. Many types of powder particle processing, including heat treating, surface modification, and thin film deposition, require a net flow of gases or vapors during at least some portion of the process cycle. This flow imparts a drag (wind) force onto the particles and may lead to yield loss as the flow of gas entrains and elutriates particles out of the reactor and into the exhaust. This is especially true for a powder containing fine cohesive particles (also called Geldart group C powder) which cannot be fluidized easily. Very fine Geldart group C powders are typically processed in a rotary drum reactor, where particle agitation is not performed by the gas flow. Longer residence time for particles to be exposed to the gas stream can be achieved in the rotary drum reactor, which is beneficial for coating efficiency. However, even then the gas or vapor flow across the reactor may cause particle elutriation, lower process efficiency, and particle loss in the exhaust stream.

Elutriated particles result in yield loss of the product. They can also cause problems for the equipment, including contamination of valves and components, clogging of filters, and saturation of cyclone separators. It is desirable to confine as much of the fine powder particles inside the reactor as possible to increase product yield and reduce contamination or other issues associated with entrained particles.

### SUMMARY

The present disclosure provides a powder treatment system that varies the speed of rotation of a treatment vessel containing the powder at different stages of the treatment process. During treatment stages where a net gas flow may be present (e.g. evacuation of the treatment vessel), the treatment vessel is spun at a speed sufficient to centrifugally force the particles of the powder against the inner surface of the treatment vessel resulting in a toroidal bed of particles on the inner surface of the treatment vessel. This is referred to hereinafter as rotation at “a centrifugal speed”. During treatment stages where gas flow may be minimal or introduced into the treatment vessel in such a way as to avoid or substantially minimize disturbance of the particle, the rotational speed of the treatment vessel is less than a centrifugal speed, such that particles within the treatment vessel do not form a toroid against the inner surface of the treatment vessel, but rather disengage from the inner surface of the treatment vessel, and fall into a reaction zone. This is referred to hereinafter as rotation at “a cataracting speed”. As those skilled in the art reading this disclosure will appreciate, at a cataracting speed some portion of the particles may be temporarily elevated within the treatment vessel due to rotation, but fall back toward the bottom of the treatment vessel due to gravity. At a cataracting speed, the powder flows, rolls, tumbles, cascades, and “aerates” by a combination of gravity, and rotational inertia imparted by the treatment vessel.

To assist disengagement of the particles from the inner surface of the treatment vessel and break up any agglomerates when operating at a cataracting speed, the present powder treatment system includes a comb, that can be moved from a first position during rotation of the treatment vessel at a centrifugal speed, to a second position during rotation of the treatment vessel at a cataracting speed. When in the first position, the comb is not in contact with the toroid of particles formed against the inner surface of the treatment vessel. When in the second position, the comb encourages separation of the particles from the inner surface of the treatment vessel. In aspects, a system for treating fine powder particles in accordance with the present disclosure includes a rotary treatment vessel configured to expose a plurality of particles to treatment gases or vapors. A controller is configured to rotate the rotary treatment vessel at a first rotation speed to establish a cataracting condition, and at a second rotation speed to establish a centrifuging condition. A comb is movable from a first position while the rotary treatment vessel is rotated at the first rotation speed, to a second position while the rotary treatment vessel is rotated at the second rotation speed.

Implementations of the above embodiment may include one or more of the following features. According to one aspect of the above embodiment, the comb may rotate from the first position to the second position. According to one aspect of the above embodiment, the comb may translate longitudinally in a direction parallel to a longitudinal axis of the rotary treatment vessel from the first position to the second position. The first rotation speed may be less than 100 RPM. The second rotation speed may be greater than 15 RPM. The system may further include one or more gas injectors configured to intermittently introduce treatment gases or vapors into the rotary treatment vessel while the rotary treatment vessel rotates at the first rotation speed. The one or more gas injectors may be configured to uniformly raise a pressure inside the rotary treatment vessel. The system may further include a vacuum port with an isolation valve to intermittently exhaust treatment gases or vapors from the rotary treatment vessel while the rotary treatment vessel rotates at the second rotation speed. The comb may include rake-shaped tines configured to break up agglomerates formed by the plurality of particles, and movement of the comb to the first position places the tines into contact with at least a portion of the plurality of particles, and movement of the comb to the second position places the tines out of contact with the plurality of particles. The rotary treatment vessel may be mounted horizontally. The system may include a plurality of radially arrayed rotary treatment vessels, wherein the controller rotates the plurality of rotary treatment vessels at the second rotation speed around a common axis of rotation. Each rotary treatment vessel of the plurality of rotary treatment vessels may define a longitudinal axis, and the controller may rotate each rotary treatment vessel of the plurality of rotary treatment vessels at the first rotation speed around its respective longitudinal axis.

According to another embodiment of the present disclosure, a method for treating fine powder particles is provided. The method includes: loading particles into a rotary treatment vessel; evacuating gas from the rotary treatment vessel while the rotary treatment vessel rotates at a centrifugal speed; and introducing treatment gas or vapor into the rotary treatment vessel while the rotary treatment vessel rotates at a cataracting speed.

Implementations of the above embodiment may include one or more of the following features. According to one aspect of the above embodiment, the loading of particles into the rotary treatment vessel may include loading Geldart group C powder into the rotary treatment vessel. The method may further include, while the rotary treatment vessel rotates at the cataracting speed, moving a comb to a first position into contact with a toroid of particles formed while the rotary treatment vessel rotates at the centrifugal speed. The method may further include mounting the rotary treatment vessel within a stationary vacuum chamber prior to rotating the rotary treatment vessel at either the cataracting speed or the centrifugal speed. Introducing treatment gas or vapor into the rotary treatment vessel may result in deposition of a coating on the particles. Introducing treatment gas or vapor into the rotary treatment vessel may be done under conditions that result in at least one of chemical vapor deposition, physical vapor deposition, plasma deposition, electrochemical deposition, molecular layer deposition, or atomic layer deposition.

### BRIEF DESCRIPTION OF THE DRAWINGS

The present disclosure may be understood by reference to the accompanying drawings, when considered in conjunction with the subsequent, detailed description, in which:

FIG. 1 schematically shows an example powder treatment system with the comb engaged in the toroid of particles in accordance with aspects of the present disclosure;

FIG. 2 schematically shows the powder treatment system of FIG. 1 with the comb disengaged from the toroid of particles in accordance with aspects of the present disclosure;

FIG. 3 shows a cross-sectional front perspective view of an example of a rotary treatment vessel assembly for use with a powder treatment system in accordance with aspects of the present disclosure;

FIG. 3A shows a cross-sectional view of the rotary treatment vessel assembly of FIG. 3;

FIGS. 3B schematically shows a cross-sectional view along line 3B-3B of FIG. 3A;

FIGS. 3C and 3D schematically show a cross-sectional view similar to FIG. 3B of alternative embodiments in accordance with aspects of the present disclosure with the shaft of the comb assembly located in different positions;

FIG. 3E shows a front perspective view of another embodiment of a rotary treatment vessel assembly in accordance with aspects of the present disclosure where the comb assembly retracts longitudinally, rather than rotating;

FIG. 4A is a rear perspective view showing the rotary treatment vessel assembly of FIG. 3 mounted on a powder treatment system prior to positioning within the stationary vacuum chamber in accordance with aspects of the present disclosure;

FIG. 4B is a rear perspective view showing the rotary treatment vessel assembly of FIG. 3 partially positioned within the powder treatment system with the heater removed to show the stationary vacuum chamber;

FIG. 4C is a front perspective view showing the rotary treatment vessel assembly of FIG. 3 fully positioned within the powder treatment system with the heater removed to show the stationary vacuum chamber;

FIG. 5 shows the rotary treatment vessel assembly of FIG. 3 positioned within the stationary vacuum chamber in accordance with aspects of the present disclosure;

FIG. 6 is a flow chart showing an exemplary method of treating a powder in accordance with aspects of the present disclosure;

FIG. 7 schematically shows another example of a powder treatment system in accordance with aspects of the present disclosure where the rotary treatment vessel is angled relative to a horizontal mounting surface;

FIGS. 8A and 8B schematically show another example of a powder treatment system in accordance with aspects of the present disclosure where multiple rotary treatment vessels are employed within a single stationary vacuum chamber and spun on a common axis;

FIGS. 9A and 9B schematically show another example of a powder treatment system in accordance with aspects of the present disclosure where multiple rotary treatment vessels are employed within a single stationary vacuum chamber and spun on individual, planetary axes;

FIG. 10A shows a cross-sectional view of another example of a rotary treatment vessel assembly for use with a powder treatment system in accordance with aspects of the present disclosure; and

FIGS. 10B and 10C show a cross-sectional views of the rotary treatment vessel assembly of FIG. 10A being assembled.

### DETAILED DESCRIPTION

Embodiments of the presently disclosed powder treatment systems are described in detail with reference to the drawings, in which like reference numerals designate identical or corresponding elements in each of the several views. In the following description, well-known functions or constructions are not described in detail to avoid obscuring the present disclosure in unnecessary detail.

Reference is made in detail to specific embodiments, one or more examples of which are illustrated in the drawings. Each example is provided by way of explanation, not limitation. It will be apparent to those skilled in the art that various modifications and variations may be made in the embodiments without departing from the scope or spirit of the disclosure. For instance, features illustrated or described as part of one embodiment may be used with another embodiment to yield a still further embodiment. Thus, it is intended that the present disclosure covers such modifications and variations as come within the scope of the appended claims and their equivalents.

The powder treatment systems described herein are particularly useful for treating fine powders. Generally, powders become more difficult to handle as their sizes become smaller because strong interparticle forces make the fine particles agglomerate and the powder cohesive. The Geldart Powder Classification divides all powders into four groups and uses letters A-D. Geldart groups A and B powders are generally in the range of 25 to 900 microns. Group D powders are about 700 microns to several millimeters in size. Group C powders are those smaller than about 30 microns and are very cohesive. The cohesive nature of Group C powder comes from the fact that when the particle size becomes smaller, the relative magnitude of the interparticle forces (e.g., the van der Waals force, the electrostatic force, and the capillary force) increases significantly in relation to the gravitational and drag forces exerted on the particles. Such strong interparticle forces make the individual particles cling to each other and therefore form agglomerates. While the following description is directed to the treatment of fine particles (e.g., Geldart group C particles), it should be understood that the structures and methods described herein may be used in connection with treatment of powder having any particle size.

While the following description is directed to the exemplary powder treatment systems shown in the figures, it should be understood that the structures and methods described herein may be used in connection with any powder treatment system, especially systems designed for applying materials (e.g., a coating, a nanotube, etc.) to particles, such as, for example a chemical vapor deposition (CVD) system, a physical vapor deposition (PVD) system, a plasma deposition system, an electrochemical deposition system, a molecular layer deposition system, or an atomic layer deposition system. Other types of powder treatment systems with which the present structures and methods may be used or adapted for use will be readily apparent to one skilled in the art reading this disclosure.

Directional terms such as top, bottom, and the like are used simply for convenience of description and are not intended to limit the disclosure attached hereto. Also, as used herein, the term “on” includes being in an open or activated position, whereas the term “off” includes being in a closed or inactivated position. As used herein, the terms “first”, “second”, and “third” may be used interchangeably to distinguish one component from another and are not intended to signify location or importance of the individual components.

Powder treatment systems in accordance with the present disclosure vary the speed of rotation of a rotary treatment vessel containing the powder to be treated depending upon the presence or absence of net gas flow through the treatment vessel at different stages of the treatment process. During treatment stages where gas flow may be present (e.g. pump down), the treatment vessel is spun at a centrifugal speed. During treatment stages where net gas flow may be minimal or introduced into the treatment vessel in such a way as to avoid or substantially minimize disturbance of the particles, the rotational speed of the treatment vessel is at a cataracting speed, which is less than a centrifugal speed. Cataracting (with or without a comb) is the condition under which the uniform processing (heat treatment, surface modification, thin film deposition, etc.) should take place for best results. This is also the condition that is most susceptible to elutriation since the fine powder particles are distributed evenly and falling throughout the reactor by design and therefore are easily entrained in any net gas or vapor flow through the reactor. Entrained particles will be elutriated out the exhaust resulting in yield loss or equipment issues including contamination of valves, clogging of filters etc. By ensuring that, during treatment stages, any net gas flow may be minimal or introduced into the treatment vessel in such a way as to avoid or substantially minimize disturbance of the particles, elutriation losses or equipment issues are avoided or substantially reduced.

It is unavoidable that some stages of the treatment process require a net flow of gases or vapors (e.g., pump down). By increasing the rotational speed of the rotary treatment vessel, one can achieve rotation at a centrifuging speed whereby the powder particles are confined to the walls of the drum. Under this condition, provided the centrifugal force is sufficiently high, it can exceed the drag forces from gas and vapor flow such that the particles will not get entrained or elutriated into the exhaust. Exploiting the centrifuging condition for confinement of the fine powder particles during treatment stages that require a net flow of gases or vapors in order to mitigate elutriation is disclosed.

During centrifuging, the particles form a compacted torus around the circumference of the rotary drum reactor. This condition is very useful for enabling high net flow through the chamber without powder elutriation. Therefore, in exemplary treatment processes in accordance with the present disclosure, a process sequence may be employed whereby there is only net gas/vapor flow at centrifugal confinement condition, for example during pump down and evacuation of the vacuum rotary drum reactor. There should be no, or substantially no net flow of gas or vapor during the cataracting condition where the uniform powder processing is being performed.

In embodiments, the reactor is evacuated under the centrifuging condition and backfilled evenly and uniformly with the process gas/vapor under the cataracting condition. This sequence can be repeated many times to achieve the required particle processing time. By backfilling the reactor uniformly without any net flow to the exhaust, elutriation to any appreciable extent will be avoided.

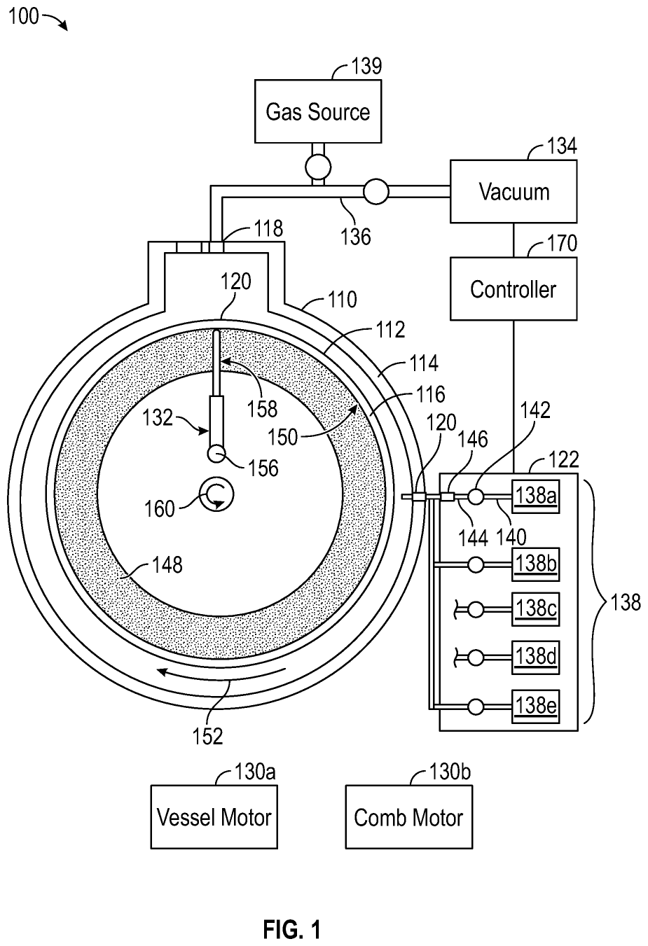

FIG. 1 schematically illustrates a reactor system 100 for treating particles. Reactor system 100 includes a stationary vacuum chamber 110 that encloses a rotary treatment vessel 112. Stationary vacuum chamber 110 is enclosed by outer chamber walls 114. Rotary treatment vessel 112 is enclosed by inner chamber walls 116. Chamber walls 114 and 116 can be a material, e.g., quartz, stainless steel, that is inert to the particle treatment process, and/or the interior surfaces of chamber walls 114 and 116 can be coated with a material that is inert to the treatment process.

A cross-section of rotary treatment vessel 112 (e.g., as viewed along the central axis of the cylinder) can be uniform along the length of the vessel 112 (the length is along the central axis of the cylinder). This can help ensure uniform treatment along the length of the chamber. Rotary treatment vessel 112 can have any suitable diameter. In embodiments, the diameter of rotary treatment vessel 112 is from about 10 mm to about 500 mm or greater.

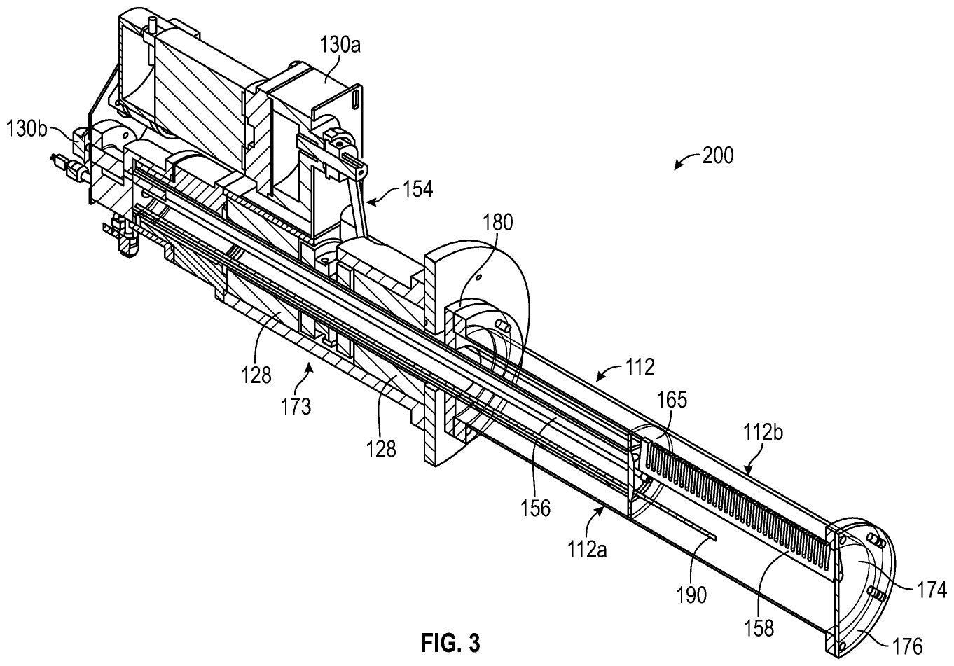

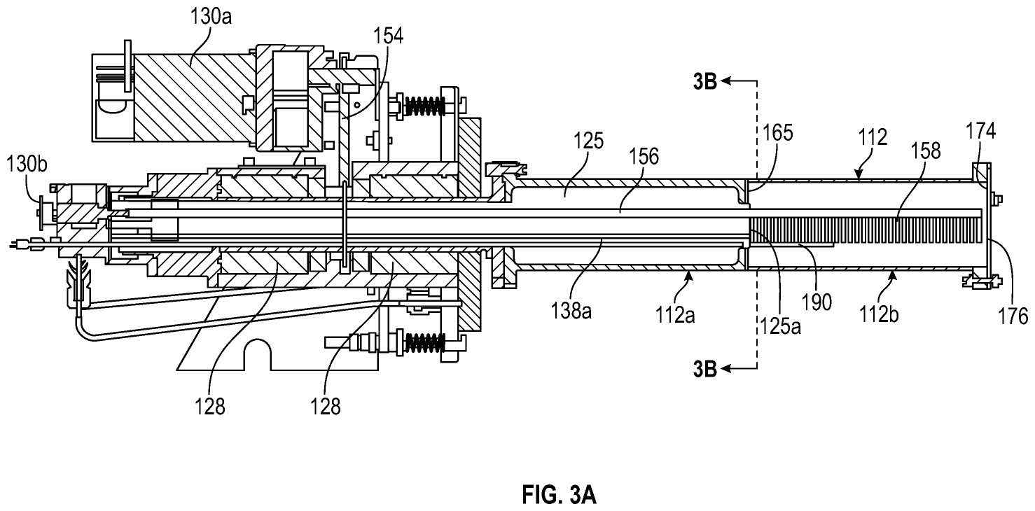

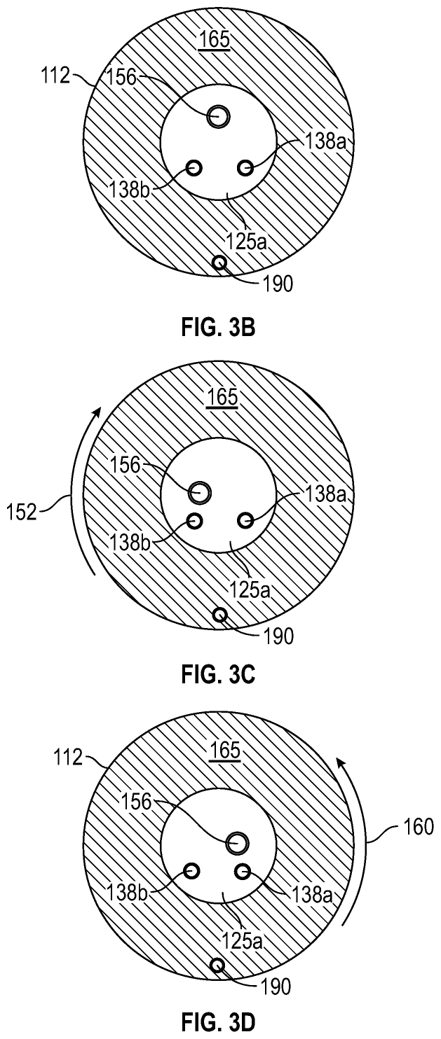

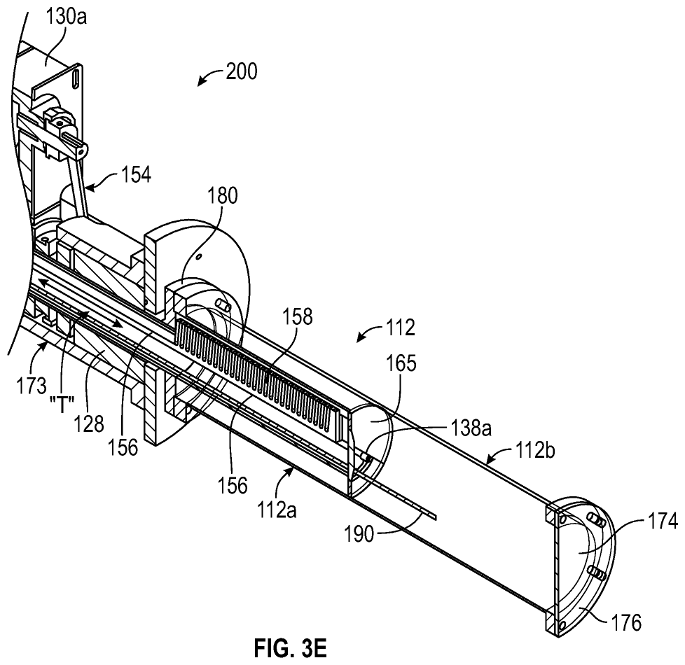

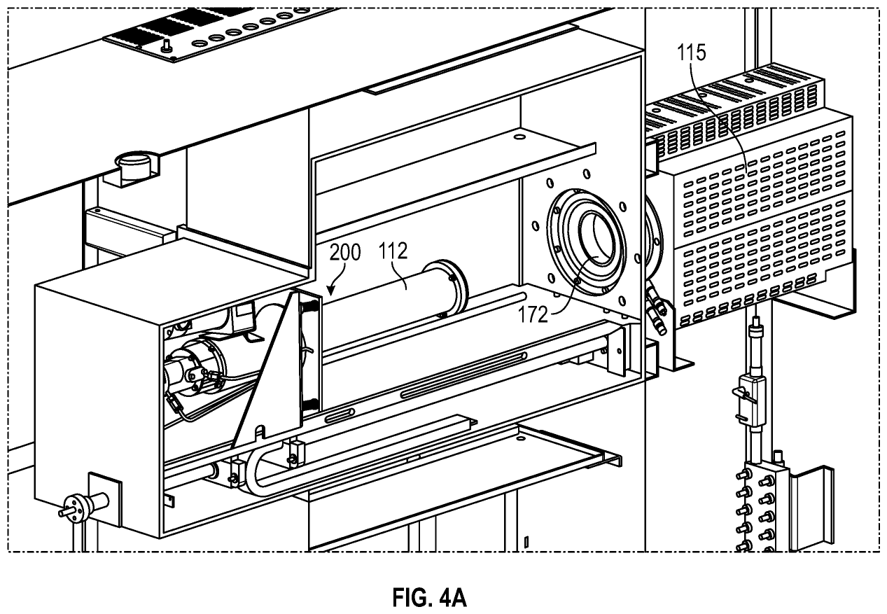

In some implementations such as the rotary treatment vessel assembly 200 shown in FIG. 3, rotary treatment vessel 112 includes a stationary support tube 125, the end surface 125a of which abuts a divider 165 that is positioned within rotary treatment vessel 112 and separates rotary treatment vessel 112 into a proximal portion 112a, and a treatment portion 112b.

Stationary vacuum chamber 110 can include one or more vacuum ports 118 for exhausting gas, e.g., treatment gas/vapor, from stationary chamber 110 and rotary treatment vessel 112. Stationary vacuum chamber 110 includes a gas inlet port 120 coupled to a chemical delivery system 122 located outside of stationary vacuum chamber 110.

System 100 includes one or more motors 130a, 130b configured to provide torque that translates into rotary motion of one or more components of the system 100. Motors 130a, 130b can be, for example, a vessel motor 130a and a comb motor 130b. Motors 130a, 130b can be, for example, brushless direct current (DC) motors, stepper motors, etc. In some implementations, motors 130a, 130b have gear reduction built in, e.g., at a ratio of 20:1.

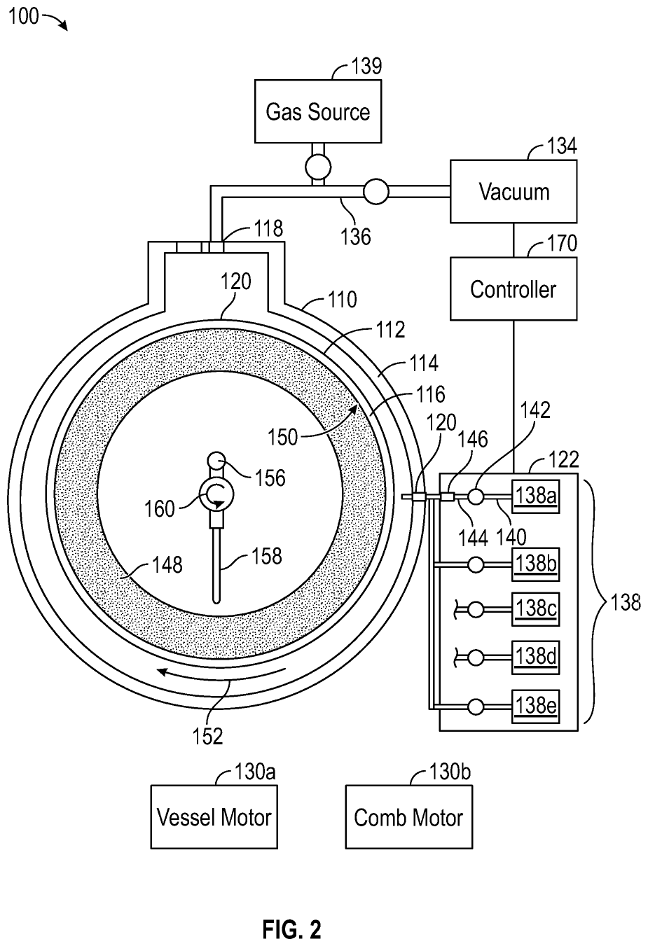

The vessel motor 130a is coupled to rotary treatment vessel 112 and configured to provide torque that is translated into rotary motion of rotary treatment vessel 112 during operation of system 100. Comb motor 130b is coupled to a comb assembly 132 and configured to provide torque that is translated into rotary motion of comb assembly 132 (e.g., 180° rotation) during operation of system 100. Though described with reference to FIGS. 1 and 2 as a vessel motor 130a and a comb motor 130b, fewer or more motors can be configured to provide torque that translates into rotary motion of the one or more components of system 100.

System 100 includes a vacuum source 134 (e.g., one or more vacuum pumps) coupled to vacuum port 118 via a gas exhaust manifold 136. Vacuum source 134 is configured to establish vacuum within stationary vacuum chamber 110 and rotary treatment vessel 112. Vacuum source 134 can be an industrial vacuum pump sufficient to establish pressures less than 1 Torr, e.g., 1 to 100 mTorr, in embodiments, 50 mTorr. Vacuum source 134 permits stationary vacuum chamber 110 and rotary treatment vessel 112 to be maintained at a desired pressure, and permits removal of reaction byproducts and unreacted treatment gases/vapors.

Chemical delivery system 122 may include one or multiple fluid sources 138, controllable valves 142, and a fluid supply line 144. Chemical delivery system 122 injects the fluid in a vapor form into stationary vacuum chamber 110 via gas inlet port 120. Chemical delivery system 122 can include a combination of restrictors, gas flow controllers, pressure transducers, source evaporators, and thermal mass flow controllers/meters (not shown) to provide controllable flow rate of the various gases and vapors into stationary vacuum chamber 110. Chemical delivery system 122 can also include one or more temperature control components (not shown), e.g., a heat exchanger, resistive heater, etc., to heat or cool the various gases/vapors before they flow into stationary vacuum chamber 110. Treatment gas/vapor delivered to stationary vacuum chamber 110 may enter rotary treatment vessel 112 to treat powder particles contained therein.

Chemical delivery system 122 can include multiple fluid sources. Two of the fluid sources, e.g., sources 138a, 138b, can provide two chemically different precursors or reactants for a treatment process, e.g., for forming a metal oxide layer on the particles. For example, first source 138a can provide trimethylaluminum (TMA) or titanium tetrachloride (TiCl₄), whereas second source 138b can provide water. Another two of the sources, e.g., sources 138c, 138d, can provide two chemically different precursors or reactants for a second treatment process, e.g., for forming a metal on the metal oxide layer. For example, third source 138c can provide silane gas, and fourth source 138d can provide tungsten hexafluoride (WF₆). One of the fluid sources, e.g., the fifth source 138e, can provide an inert gas, e.g., argon, helium, or nitrogen, for purging between cycles or half-cycles in the treatment process.

Although FIG. 1 illustrates five fluid sources, the use of fewer gas sources could still be compatible with the treatment process, and use of more gas sources could enable formation of an even wider variety of treated particles.

Chemical delivery system 122 can include a vaporizer 146 to convert the liquid to vapor immediately before the precursor or reactant enters a gas inlet 120. Vaporizer 146 can be immediately adjacent the outer wall of stationary vacuum chamber 110, e.g., secured to or housed adjacent to gas inlet port 120.

Rotary treatment vessel 112 is encapsulated within and supported by stationary vacuum chamber 110. Rotary vacuum chamber 112 includes an inner surface 150 along an inner diameter of chamber walls 116. In some implementations, as depicted in FIGS. 2 and 3, rotary treatment vessel 112 includes a cylindrical portion, where an axis of rotation is aligned on a center axis of the cylinder. Rotary treatment vessel 112 is connected to stationary vacuum chamber 110 by any suitable securement means as depicted, for example, in FIG. 3

In some embodiments, inner surface 150 is roughened to permit friction of the particles 148 with the inner surface 150 of the rotary treatment vessel 112. Depending on the nature of the particles, some friction via surface roughness may be advantageous to ensure momentum is imparted to the particles during rotation.

Rotary treatment vessel 112 is coupled to motor 130a operable to generate torque that can translate into rotary motion of rotary treatment vessel 112 in a first direction 152 (e.g., clockwise). The coupling between rotary treatment vessel 112 and motor 130a can be through a rotary motion vacuum feedthrough 128 (see FIG. 3). One or more mechanical couplings, such as belt and pulley system 154 (see FIG. 3) can be utilized between motor 130a and rotary treatment vessel 112 to translate a torque output from motor 130a into a rotary motion in the first direction 152 of the rotary treatment vessel 112. Motion of rotary treatment vessel 112 can be clockwise (CW), counter-clockwise (CCW), or can alternate between CW and CCW.

Comb assembly 132 includes a shaft 156 and a comb 158 coupled to shaft 156. Shaft 156 is oriented parallel to the longitudinal axis of rotary treatment vessel 112 and is positioned off centerline to enable engagement and disengagement with toroidally distributed powder. In the embodiments shown in FIGS. 3-5, shaft 156 passes through end surface 125a of stationary support tube 125 and into rotary treatment vessel 112 such that shaft 156 rotates freely with respect to rotary treatment vessel 112 and stationary support tube 125. A seal (not shown) can be located between end surface 125a of stationary support tube 125 and rotary treatment vessel 112 to prevent powder in rotary treatment vessel 112 from traveling down shaft 156 to the bearings of rotary motion feedthrough 128.

Comb 158 is affixed to shaft 156 along the length of shaft 156. Particle treatment systems in accordance with the present disclosure, therefore, use a retractable comb 158 so that the tines of the comb can be moved out of the particle bed during the centrifuging condition and back into the path of particle motion during the cataracting (processing) condition. Engagement of comb 158 in and out of the particle motion path can be achieved by 1/2 turn rotation of the comb shaft 156. In FIG. 1, comb 158 is positioned such that an outer surface of comb 158 is spaced a small distance from inner surface 150 of treatment vessel 112. Comb 158 has rake-like tines that assist with fine powder particle processing in rotary treatment vessel 112. Without comb 158, fine particles may fall in the cataracting condition as agglomerates rather than individual particles, and the particle processing uniformity will suffer. In FIG. 2, comb 158 is positioned out of engagement with particles 148 so as not to interfere with toroid formation when rotary treatment vessel 112 is rotating at a centrifugal speed. Those skilled in the art reading this disclosure will readily envision other ways, including motorized motion (translating or rotating into/out of the path of particle motion) or pneumatic actuation (for example extension and retraction of the comb tines via pneumatic pressure) to move comb 158. Processing of fine cohesive (e.g., Geldart group C) particles may benefit from contact with the rake-like tines of comb 158 which break up particle agglomerates during cataracting. This improves the spatial separation of particles before they fall, and leads to more uniform processing of the particles.

In embodiments, shaft 156 of comb assembly 132 may be positioned in vertical alignment with the center axis of rotary treatment vessel 112 as shown in FIGS. 1-3B. In other embodiments, shaft shaft 156 of comb assembly 132 may pass through end surface 125a of stationary support tube 125 radially offset from the center axis of rotary treatment vessel 112 so that as particles fall through the reaction zone, they do not land on and are not inhibited from falling uniformly by interaction with comb assembly 132. Thus, for example as shown in FIG. 3C, when rotary treatment vessel 112 is rotated in direction 152, it might be advantageous to locate shaft 156 of comb assembly 132 closer to the 9 o'clock position relative to the center axis of rotary treatment vessel 112. On the other hand, when rotary treatment vessel 112 is rotated in direction 160, for example as shown in FIG. 3D, it might be advantageous to locate shaft 156 of comb assembly 132 closer to the 3 o'clock position relative to the center axis of rotary treatment vessel 112.

Comb assembly 132 is coupled to comb motor 130b, via rotary vacuum feedthrough (e.g., including vacuum-compatible bearings; see FIG. 3). Comb motor 130b is configured to apply torque to shaft 156 such that shaft 156 rotates about a center axial axis parallel to, but not aligned with the longitudinal axis of rotary treatment vessel 112. One or more mechanical couplings can be utilized between comb motor 130b and shaft 156 to translate a torque output from comb motor 130b into a rotary motion in the second direction 160 (e.g., counter-clockwise) of comb assembly 132. In embodiments, shaft 156 is rotated 180° from a first, downward disengaged position (FIG. 2) where comb 158 is not in contact with the toroid of particles formed by rotating the rotary treatment vessel 112 at a centrifuging speed, to a second, upward engaged position (FIG. 1) where comb 158 contacts the toroid of particles to disengage them from inner surface 150 of rotary treatment vessel 112 when rotary treatment vessel 112 is rotating at a cataracting speed. It should of course be understood that rotation of shaft 156 may be more or less than 180°. Motion of shaft 156 can be clockwise (CW) or counter-clockwise (CCW).

It should be understood that while comb 158 may be translated into and out of contact with the toroid of particles by rotating shaft 156, it is also contemplated that comb 158 may be translated into and out of contact with the toroid of particles by translating shaft 156 longitudinally. An exemplary embodiment of such an alternative embodiment is shown in FIG. 3E where shaft 156 of comb assembly 132 may be translated in the direction of arrow “T” into and out of treatment portion 112b of rotary treatment vessel 112, and hence move comb 158 into and out of contact with the toroid of particles. It should, of course be understood that a combination of rotary and longitudinal translation may be employed in embodiments to move comb 158 into and out of contact with the toroid of particles.

In some implementations such as the rotary treatment vessel assembly 200 shown in FIG. 3, rotary motion vacuum feedthrough 128 is a bearing vacuum seal that can be used to seal rotary treatment vessel 112 from the external environment. It should be understood that other types of rotary unions other than a ferro fluid type may be employed, such as a lip seal or a magnetic drive.

In some implementations, first direction 152 and second direction 160 are opposite directions, e.g., clockwise and counter-clockwise. It should of course be understood that first direction 152 and second direction 160 can instead be in a same direction, e.g., both clockwise or both counter-clockwise.

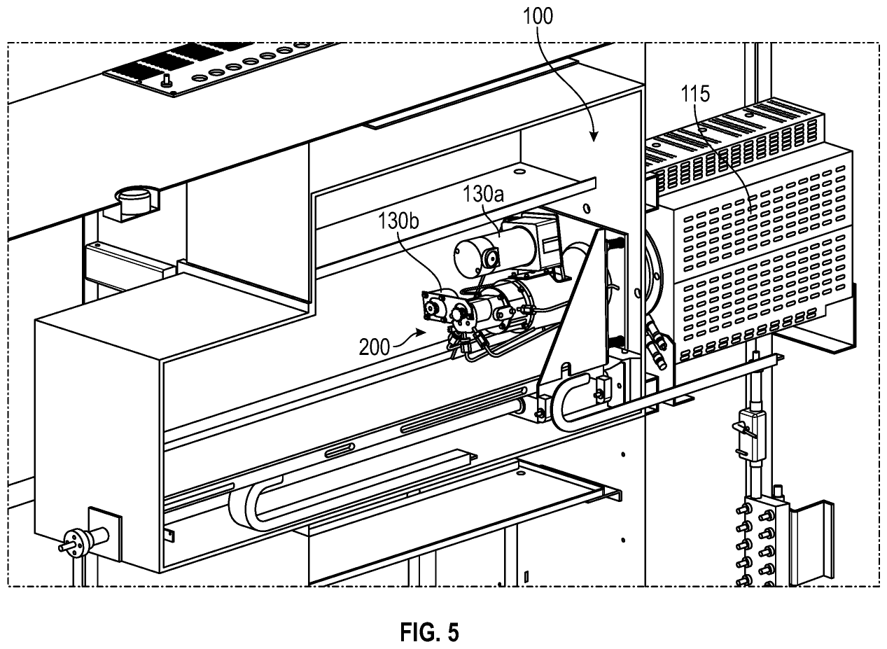

In some implementations, one or more temperature control components are integrated into or surround inner chamber walls 116 to permit control of the temperature of stationary vacuum chamber 110 and rotary treatment vessel 112. For example, resistive heater, a thermoelectric cooler, a heat exchanger, or coolant flowing in cooling channels in the chamber wall, or other component in or on side walls 116. A thermocouple 190 may pass through end surface 125a of stationary support tube 125 and into rotary treatment vessel 112 so as to be positioned at the reaction zone within treatment portion 112b of rotary treatment vessel 112. Thermocouple 190 may provide continuous or intermittent measurements of the temperature at the reaction zone, and to transmit signals reflective of such temperature to controller 170 so controller 170 may automatically activate or de-activate a heater 115 (FIG. 5) to maintain a suitable treatment temperature.

System 100 further includes a controller 170 that is operable to control the actions of chemical distribution system 122 and motors 130a, 130b. Controller 170 can be configured to operate comb motor 130b to generate a rotary motion of comb assembly 132. Controller 170 can be further configured to operate the vessel motor 130a to generate a rotary motion of the rotary treatment vessel 112 in first direction 152 at rotational speeds up to 300 rpm, for example, at speeds ranging from 50 to 150 rpm. In some implementations, controller 170 is configured to operate the vessel motor 130a to produce a rotational speed of the rotary treatment vessel 112 suitable for each phase of the treatment process. At times during the treatment process, vessel motor 130a produces a rotational speed of the rotary treatment vessel 112 that exceeds a threshold rotational motion, e.g., that is greater than 15 rpm, that is sufficiently high that particles 148 are centrifugally forced against inner surface 150 of the rotary treatment vessel 112. As previously noted, this is referred to hereinafter as rotation at “a centrifugal speed” and results in a toroidal bed of particles 148 on inner surface 150. An amount of compression of the bed of particles formed by the fast rotary motion of rotary treatment vessel 112 can depend, for example, on the rotational speed of the rotary treatment vessel 112. At other times during the treatment process, vessel motor 130a produces a rotational speed of rotary treatment vessel 112 that does not centrifugally force particles 148 against inner surface 150 of the rotary treatment vessel 112, but rather allows particles 148 to disengage from inner surface 150 of rotary treatment vessel 112. As previously noted, this is referred to hereinafter as rotation at “a cataracting speed” and results in particles 148 falling across the width of rotary treatment vessel 112 for treatment. Controller 170 can also be coupled to various sensors (not shown), e.g., pressure sensors, flow meters, etc., to provide closed loop control of the rotation rate of rotary treatment vessel 112 and the pressure of the gases in stationary chamber 110.

In general, controller 170 is configured to operate reactor system 100 in accordance with a “recipe.” The recipe specifies an operating value for each controllable element as a function of time. For example, the recipe can specify the times during which vacuum source 132 is to operate, the times of and flow rate for each gas source 138a-138e, the rotation rate of rotary treatment vessel 112 and shaft 156 as set by motors 130a, 130b, etc. Controller 170 can receive the recipe as computer-readable data (e.g., that is stored on a non-transitory computer readable medium).

Controller 170 may include a discrete processor and memory unit (not pictured). Controller 170 may include any suitable processor operably connected to a memory (not shown), which may include one or more of volatile, non-volatile, magnetic, optical, or electrical media, such as read-only memory (ROM), random access memory (RAM), electrically-erasable programmable ROM (EEPROM), non-volatile RAM (NVRAM), or flash memory. The processor may be configured to perform operations, calculations, and/or set of instructions described in the disclosure including, but not limited to, a hardware processor, a field programmable gate array (FPGA), a digital signal processor (DSP), a central processing unit (CPU), a microprocessor, etc. The processor may also include a microprocessor, or a combination of the aforementioned devices (e.g., a combination of a DSP and a microprocessor, a plurality of microprocessors, one or more microprocessors in conjunction with a DSP core, or any other such configuration). Those skilled in the art will appreciate that the processor may be any logic processor (e.g., control circuit) adapted to execute algorithms, calculations, and/or set of instructions described herein.

It should be understood that a single controller may be used to execute the algorithms described herein to perform all calculations and control all operations of the present system. Alternatively, two or more separate controllers may be employed to perform selected calculations and/or control selected functions while collectively performing all needed operations. Thus, for example, a first controller may be employed to control the rotational speed of vessel motor 130a, a second controller may be employed to control comb motor 130b, and a third controller may receive and process data (e.g., concentration of reactants within vessel 112) collected by a sensor (not shown) and control the release or purging of treatment gas/vapor based on such data. Those skilled in the art reading this disclosure will readily envision other combinations and configurations of controllers that may be used in carrying out the calculations and performance of functions of the algorithm described herein.

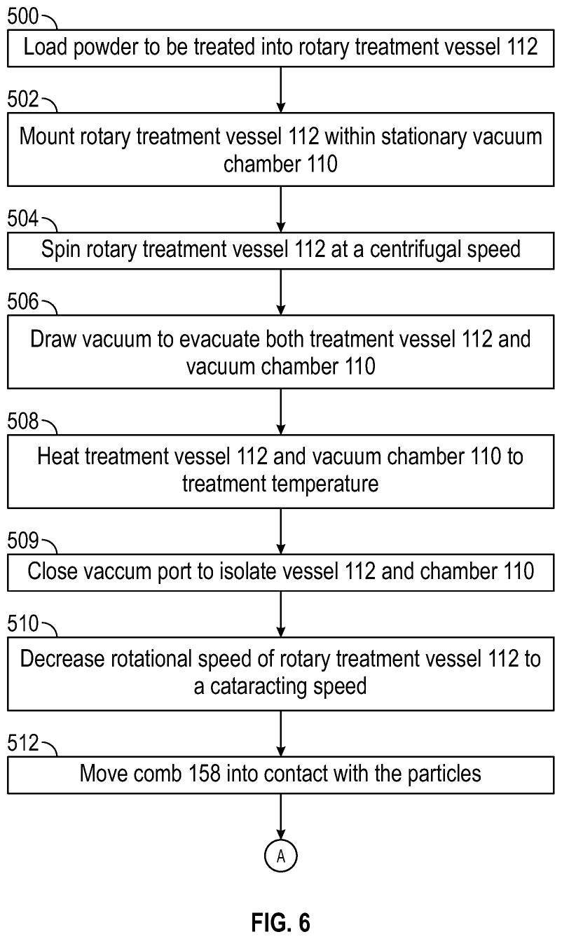

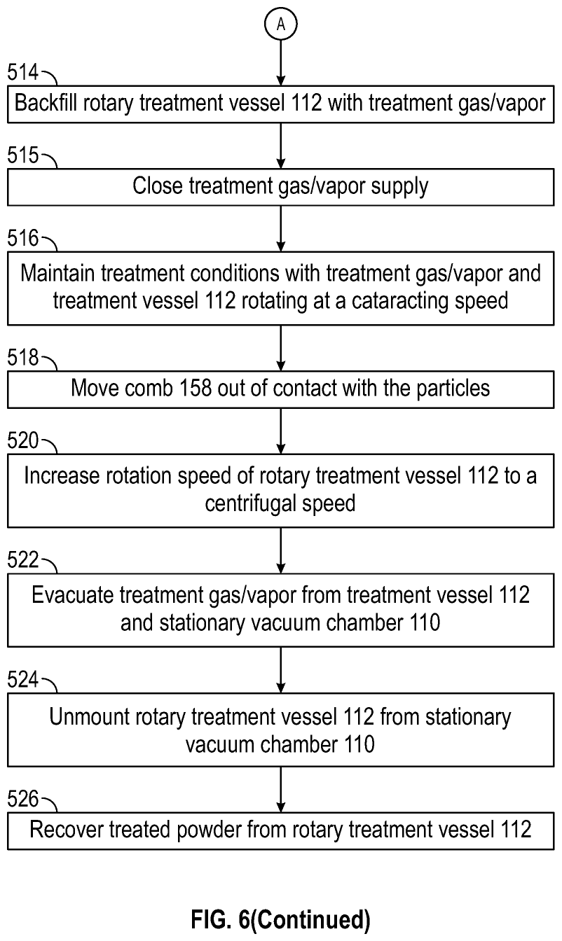

Additionally, the memory device(s) may generally include memory element(s) including, but not limited to, computer readable medium (e.g., random access memory (RAM)), computer readable non-volatile medium (e.g., a flash memory), a compact disc-read only memory (CD-ROM), a magneto-optical disk (MOD), a digital versatile disc (DVD), and/or other suitable memory elements. The memory can store information accessible by processor(s), including instructions that may be executed by processor(s). For example, the instructions may be software or any set of instructions that when executed by the processor(s), cause the processor(s) to perform operations. For the embodiment depicted, the instructions include a software package configured to operate controller 170 (or multiple controllers in certain embodiments) to, e.g., execute the exemplary method described below with reference to FIG. 6.

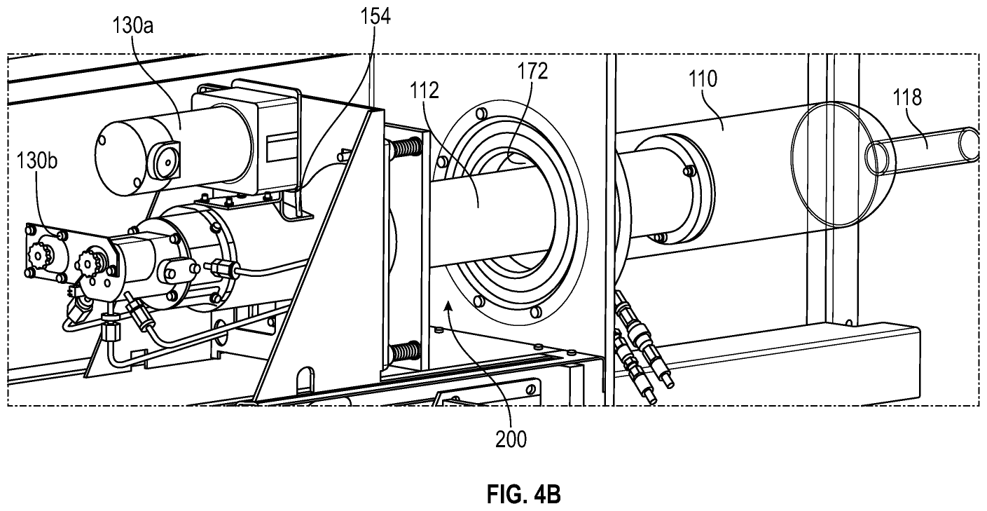

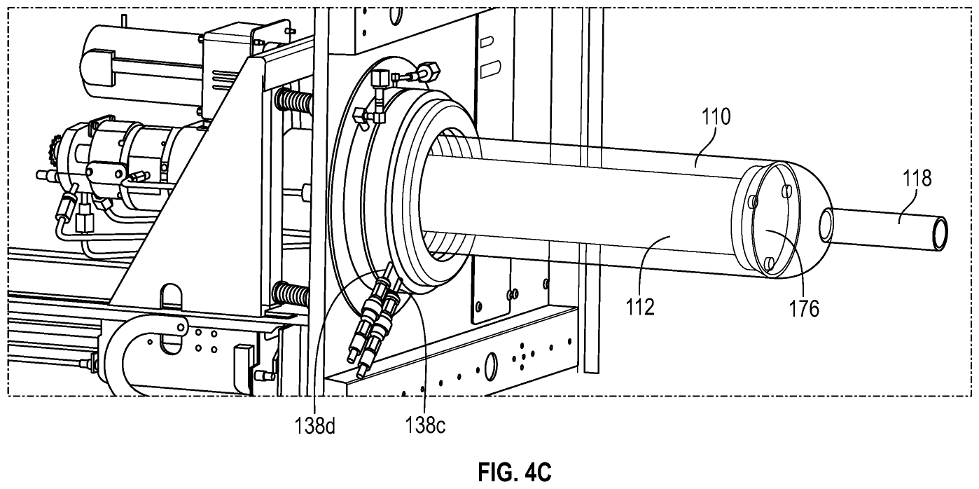

System 100 further includes a first loading port 172 located on stationary vacuum chamber 110 (see FIG. 4) and a second loading port 174 located on rotary treatment vessel 112 (see FIG. 3).

Rotary treatment vessel 112 may further include a particle filter 176 positioned over loading port 174 that allows gas to exhaust from rotary treatment vessel 112 via vacuum port 118 located in stationary vacuum chamber 110.

Rotary treatment vessel assembly 200 can include a base 173 to support rotary treatment vessel 112 on a mounting surface. As a result, assuming a horizontal mounting surface, the axis of rotation of the rotary treatment vessel 112 is perpendicular to gravity. In some implementations, rotary treatment vessel 112 may be secured to base 173 such that its longitudinal axis is at an angle relative to mounting surface, rather than parallel to the mounting surface as shown in the figures.

FIG. 6 is a flow chart showing an exemplary method for particle treatment in accordance with aspects of the present disclosure. As will be appreciated, some steps in the exemplary method may be performed manually and some steps in the exemplary method may be computer-implemented. In embodiments, however, some of the steps indicated to be performed manually may be automated and some of the computer-implemented steps may be performed manually. In addition, while the exemplary method of FIG. 6 illustrates a plurality of steps in a particular order, the steps need not all be performed in the same order as shown and may be performed in any suitable sequence and/or some steps may be omitted entirely.

Initially, a powder to be treated is loaded into rotary treatment vessel 112 at step 500. Powder may be manually loaded into rotary treatment vessel 112 by removing filter 176, and simply pouring a measured amount of powder into vessel 112. Any powder to be treated may be loaded into vessel 112. For example, the powder may be an active pharmaceutical ingredient (API), carbon or graphite particles, metal particles, or a binary, ternary, etc. compound of a nitride, a carbide, a boride, an oxide, a sulfide, a silicide, or a perovskite. Examples of fine powder particle materials for processing include C, Si, TiN, TiCN, TiC, ZrC, ZrN, VC, VN, cBN, Al₂O₃, Si₃N₄, SiB₆, W₂B₅, AlN, AlMgB₁₄, MoS₂, MoSi₂, Mo₂B₅, MO₂B, diamond, or any fine powder or combination thereof. The powder may have particles of any size, and in embodiments are fine, Group C particles. In addition, the powder may include particles of any shape, including but not limited to generally spherical, fibers or plates. After the powder is loaded, filter 176 may be replaced and rotary treatment vessel 112 attached to flange 180 (FIG. 3).

At step 502, rotary treatment vessel 112 is mounted within stationary vacuum chamber 110. To do so, rotary treatment vessel assembly 200 is advanced into opening 172 of stationary vacuum chamber 110 and sealingly secured therein as shown in FIGS. 4A-C and 5.

At step 504, rotary treatment vessel 112 is spun at a centrifugal speed. In embodiments, controller 170 activates vessel motor 130a at a speed sufficiently high that particles 148 are centrifugally forced against inner surface 150 of the rotary treatment vessel 112 thereby forming a toroid of particles. It should be noted that at this point of the treatment process, comb 158 is in a first, downward disengaged position where it is not in contact with the toroid of particles formed when the rotary treatment vessel 112 rotates at a centrifugal speed. The speed necessary to achieve formation of a toroid against the inner surface 150 of rotary treatment vessel 112 will depend on the diameter of vessel 112. The angular velocity in revolutions per minute (rpm) required to achieve centrifuging, can be calculated to first approximation, by:

$${ω}_{centrifuging} = \sqrt{\frac{g}{r}} \times \frac{60}{2 π}$$

where g is the gravitational acceleration (9.8 m/s²) and r is the radius of the rotary drum reactor in meters. Such equation is commonly used in artificial gravity calculations where a rotating spacecraft can be designed to produce 1 g of force on the occupants, simulating the gravitational force at the Earth's surface.

Using the above equation, for a 10″ inner diameter rotary drum reactor, particles on the inner wall would begin to centrifuge at angular velocities of ω_{centrifuging}≥84 rpm. For a 3″ diameter reactor, ω_{centrifuging}>153 rpm. The minimum angular velocity required for centrifuging should take into account the thickness of the powder load inside of the rotary drum chamber and use the radius at the center of the torus. These angular velocities are quite readily achievable and not prohibitively high.

There are also drag forces on the particles due to the interaction of gas and vapor molecules inside the reactor with the particles on the inner surface of the torus. Therefore, a higher angular velocity should be used to impart a higher centrifugal force than is necessary for centrifuging alone. It is desirable to use the minimum centrifugal force (minimum angular velocity) where the centrifugal confinement occurs under net gas/vapor flow. This is because at higher centrifugal forces the particles may compact more in the torus and become more difficult to break apart when slowing back to the cataracting (processing) condition. Those skilled in the art reading this disclosure will readily be able to calculate suitable rotation speeds to reach the centrifuging condition for any given vessel diameter.

At step 506, vacuum is drawn to evacuate both rotary treatment vessel 112 and stationary vacuum chamber 110 while rotary treatment vessel 112 continues to rotate at a centrifugal speed to eliminate and or minimize elutriation of particles.

At step 508, both rotary treatment vessel 112 and stationary vacuum chamber 110 are heated to a desired treatment temperature. Reactor system 100 permits a treatment process to be performed at higher (above 50° C., e.g., 50-1100° C.) or lower processing temperature (e.g., below 50° C., e.g., at or below 35° C.). In general, the particles can remain or be maintained at such temperatures. This can be achieved by having the treatment gases and/or the interior surfaces of the reactor chamber remain or be maintained at such temperatures. For example, heating can be achieved by a heater cartridge embedded in the chamber body, by a water channel in the chamber body with use of heat exchanger, or by a heater jacket on the chamber body.

At step 509, vacuum port 118 is closed to isolate the stationary vacuum chamber 110 and rotary treatment vessel 112 from the gas exhaust manifold 136.

At step 510, the rotational speed of rotary treatment vessel 112 is reduced to a cataracting speed. The rotational speed of the treatment vessel to achieve cataracting is less than a centrifugal speed. At a cataracting speed, particles within the treatment vessel do not form a toroid against the inner surface of the treatment vessel, but rather disengage from the inner surface of the treatment vessel, and fall into a reaction zone. As those skilled in the art reading this disclosure will appreciate, at a cataracting speed some portion of the particles may be temporarily elevated within the treatment vessel due to rotation, but fall back toward the bottom of the treatment vessel due to gravity. At a cataracting speed, the powder flows, rolls, tumbles, cascades, and “aerates” by a combination of centrifugal force, gravity, and rotational inertia imparted by the treatment vessel. Excellent, uniform processing occurs during the cataracting condition where the rotation speed of rotary treatment vessel 112 is sufficient to carry particles up the wall of the vessel with just enough momentum to reach the top where they fall and rain down uniformly and evenly through the center of the vessel.

Once at the cataracting speed, comb 158 is moved into contact with the particles at step 512. Controller 170 activates comb motor 130b such that shaft 156 rotates to move comb 158 to a second, upward engaged position where comb 158 contacts the toroid of particles to disengage them from inner surface 150 of rotary treatment vessel 112 while rotary treatment vessel 112 rotates at a cataracting speed.

At step 514, the rotary treatment vessel 112 is rotating at the cataracting condition and the treatment gas/vapor is backfilled evenly and uniformly. In embodiments, introduction of treatment gas/vapor results in no, or minimal net gas flow within rotary treatment vessel 112 so as to avoid or minimize disturbance of the fine powder particles. In embodiments, the introduction of treatment gas/vapor raises the pressure within rotary treatment vessel 112 to a pressure of 10 to 500 Torr; in embodiments to a pressure of 30 to 300 Torr; in embodiments to a pressure of 50 to 150 Torr. Accordingly, elutriation of particles is not a significant concern during this step. Introduction of gas directly into rotary treatment vessel 112 may be provided via lumens passing through rotary treatment vessel assembly 200 (see 138a, 138b in FIG. 3B, for example) and simultaneously into stationary vacuum chamber 110 (see 138c, 138d in FIG. 4C). Treatment gases/vapors include, but are not limited to, helium, neon, argon, krypton, xenon, hydrogen, air, carbon monoxide, hydrogen bromide, hydrogen chloride, hydrogen fluoride, nitrogen, deuterium, oxygen, nitric oxide, hydrogen iodide, fluorine, chlorine, hydrogen sulfide, hydrogen selenide, carbon dioxide, nitrous oxide, methane, ammonia, phosphine, sulfur dioxide, methyl fluoride, carbonyl sulfide, arsine, cyanogen chloride, ethylene, silane, acetylene, germane, carbonyl fluoride, boron trifluoride, fluoroform, nitrogen trifluoride, ethane, diborane, phosgene, phosphorus trifluoride, carbon tetrafluoride, dichlorosilane, propylene, boron trichloride, perchloryl fluoride, chlorine trifluoride, dimethylamine, silicon tetrafluoride, propane, tetrafluoroethylene, disilane, germanium tetrafluoride, butene, silicon tetrachloride, trimethylamine, sulfur hexafluoride, isobutane, butane, hexafluoroethane, tungsten hexafluoride, perfluoropropane, octafluorocyclobutane, hexafluoropropylen, pentafluoroethane, difluoromethane, methylsilane, trimethylsilane, octafluorocyclopentene, hexafluoro-2-butyne, hexafluoro butadiene-1-3, epoxyperfluoro-cyclopentene, trisilylamine, dimethylethylamine, etc. Treatment gases/vapors may also include vapors of metalorganic precursors such as trimethylaluminum, dimethylselenium, trimethyl-gallium, trimethylindium, molybdenum hexacarbonyl, etc. Treatment gases/vapors may also include volatilized liquids such as water, tetraethyl orthosilicate, germanium tetrachloride, trichlorosilane, etc. Treatment gases/vapors may also include vapors of sublimated solids such as borazine, molybdenum trioxide, etc.

The treatment gas/vapor supply is closed at step 515.

The treatment conditions with the residual treatment gas/vapor are maintained for an adequate time while the rotary treatment vessel 112 spins at a cataracting speed for a desired treatment time at step 516 in order to deplete the reactants. In embodiments, this step is primarily a dwell step to allow the desired treatment to take place and typically involves no introduction of treatment gas/vapor. Because there typically is no, or minimal net gas flow within rotary treatment vessel 112 during this step, rotary treatment vessel 112 may spin at a cataracting speed to maximize reaction efficiency and elutriation of particles is not a significant concern.

Once the desired treatment is achieved, at step 518 comb 158 is moved out of contact with particles. To move the comb, controller 170 activates comb motor 130b such that shaft 156 rotates about its axis to move comb 158 back to the first, downward disengaged position where it is not in contact with the toroid of particles formed when the rotary treatment vessel 112 rotates at a centrifuging speed.

The rotational speed of rotary treatment vessel 112 is increased at step 520 to once again spin rotary treatment vessel 112 at a centrifugal speed.

As those skilled in the art reading this disclosure will appreciate, it takes time for particles to fall from the top to the bottom of the reactor. There is therefore a dwell step 521 whereby particles in free fall are given time to fall the bottom of the rotary treatment vessel 112 so that they become confined in the centrifuging torus. At atmospheric conditions the particles tend to float like a cloud and fall through the air extremely slowly. However, in the vacuum rotary drum reactor, because the density of gas that the particles are falling through is lower, the particles will reach a terminal velocity substantially higher than that for atmospheric conditions. The terminal velocity is given by the equation:

$${V}_{t} = \sqrt{\frac{2 mg}{ρ {AC}_{d}}}$$

where m is the mass of the particle, g is the gravitational acceleration, p is the density of the gas that the particle is falling through, A is the cross-sectional area of the particle, and Ca is the drag coefficient. Taking the example of a 1 μm diameter spherical pyrolytic carbon particle in a reactor at a pressure of 50 Torr of gas at 600° C., the particle will reach a terminal velocity of vt˜1.4 mm/s and will take about three minutes to fall from the top wall to the bottom wall of a 10″ inner diameter rotary drum reactor. Note that in this example the ideal gas law was used to calculate the density of the gas. Such a wait time is quite acceptable, and actual conditions (lower pressure, higher temperature, shorter path length) may reduce this wait time. Waiting for all particles in free-fall at the end of the cataracting step to fall to the bottom may not be necessary as a certain amount of yield loss from only those particles left in free fall before opening the vacuum valve and evacuating the reactor may be acceptable.

Once a centrifugal speed is achieved and any suspended particles have settled, at step 522 the treatment gas/vapor is pumped out of the rotary treatment vessel 112 and stationary vacuum chamber 110. Because the particles are again centrifugally forced against inner surface 150 of the rotary treatment vessel 112, despite the net movement of gas/vapor out of rotary treatment vessel 112, substantially no elutriation occurs.

At step 524, rotary treatment vessel 112 is unmounted from stationary vacuum chamber 110, essentially by reversing the process described above with respect to step 502.

At step 526, treated powder is recovered from rotary treatment vessel 112. Treated powder may be recovered by removing filter 176 and simply tapping rotary treatment vessel 112 on a hard surface. Alternatively, treated powder may be recovered by vacuuming the treated powder out of rotary treatment vessel 112. Those skilled in the art reading this disclosure will readily envision other ways to recover treated powder from rotary treatment vessel 112.

It should be appreciated that if multiple treatments are desired (either with the same treatment gas/vapor, or with different treatment gases/vapors), the process may return to step 509 at the end of step 522 such that steps 509-522 may be repeated any number of times. Thus, for example, in a first treatment process, a first, initial treatment gas/vapor may be introduced at step 514 to provide a first coating having a first composition on the particles. Once step 522 is complete, in a multiple treatment scenario, the process may return to step 510 and at the second occurrence of step 514 a second, similar or different treatment gas/vapor may be introduced to provide a second coating on the already coated particles. The second coating may have the same or different composition from the first composition. Those skilled in the art reading this disclosure will readily envision other process strategies to achieve multiple treatments of the particles within rotary treatment vessel 112.

Another embodiment includes the rotary drum reactor positioned at an angle to the horizontal plane to enable powder to be collected predominantly in a certain part of the reactor depending on the rotation speed, as shown in FIG. 7. Angling the system may help in several ways, for example to allow particles that have blown to one end of the rotary treatment vessel during pumpdown to fall back into the ‘sweet spot’ of the reactor upon slowing back down from centrifugal to cataracting speed. Angling the system may also encourage more mixing of the particles and hence more uniform treatment. In embodiments, rather than being positioned at a fixed angle, the system may be designed to oscillate the angle of the reactor in a see-saw motion.

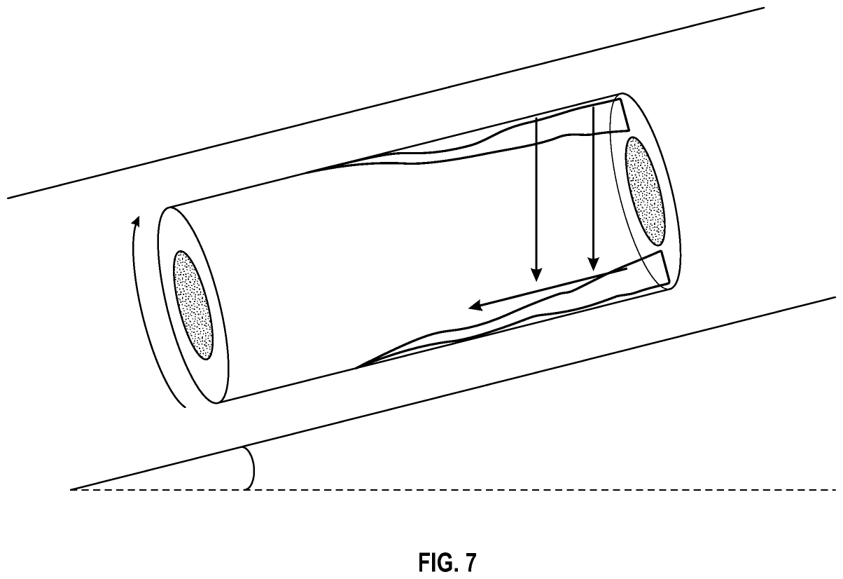

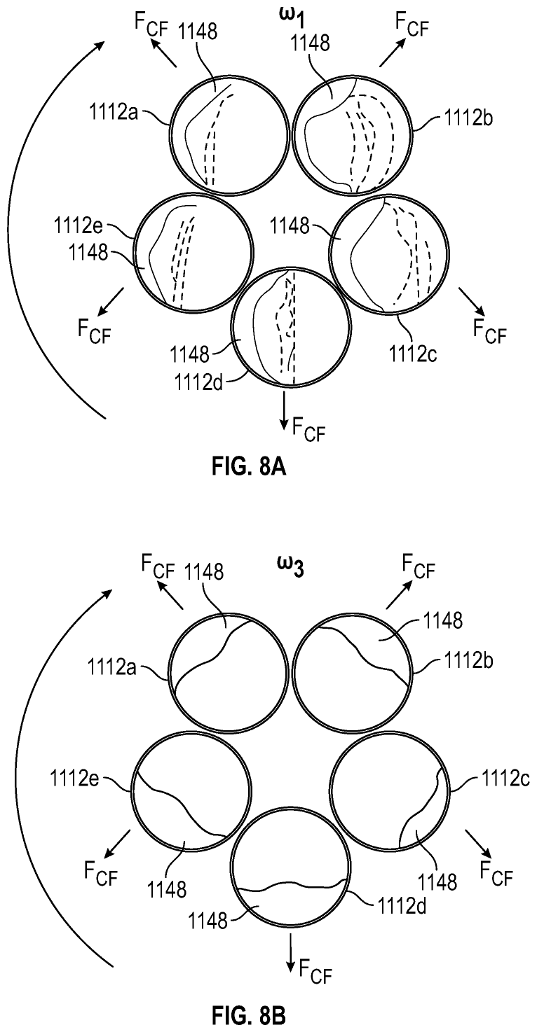

The amount of powder in the process tube ultimately defines the process time needed to efficiently coat particles in the rotary treatment vessel. For production scaleup the vessel size (e.g., diameter, length) may be increased to process more powder per run. As previously noted, however, the time it takes for particles to fall from the top to the bottom of the vessel influences the wait time before all particles have become confined in the centrifuging torus. To shorten this waiting time while still processing more powder, in an alternative embodiment, multiple rotary treatment vessels 1112a-e can be employed inside of a common stationary vacuum chamber to process larger amount of powder without significant impact on the process time, since amount of powder in each drum can be kept the same. This may also lead to better spreading and more uniform treatment of the powder. An exemplary multi-vessel embodiment is shown in FIGS. 8A and 8B, with five rotary treatment vessels 1112a-e spinning in unison at a cataracting speed (ω₁) in FIG. 8A), and in FIG. 8B spinning in unison at a centrifugal speed (ω₂). At the high speed, centrifugal rotation regime, all particles 1148 will experience centrifugal force so the time to confinement is much quicker than it would be with the axial single-reactor design. As shown in FIG. 8B, rather than forming a toroid, the particles 1148 will, upon rotation at a centrifugal speed, collect against a portion of the inner surface of each rotary treatment vessel 1112a-e. While not explicitly shown in FIGS. 8A and 8B, it should be understood that the other various structures from the previous embodiments (comb, motors, etc.) may be provided for each of the five rotary treatment vessels 1112a-e.

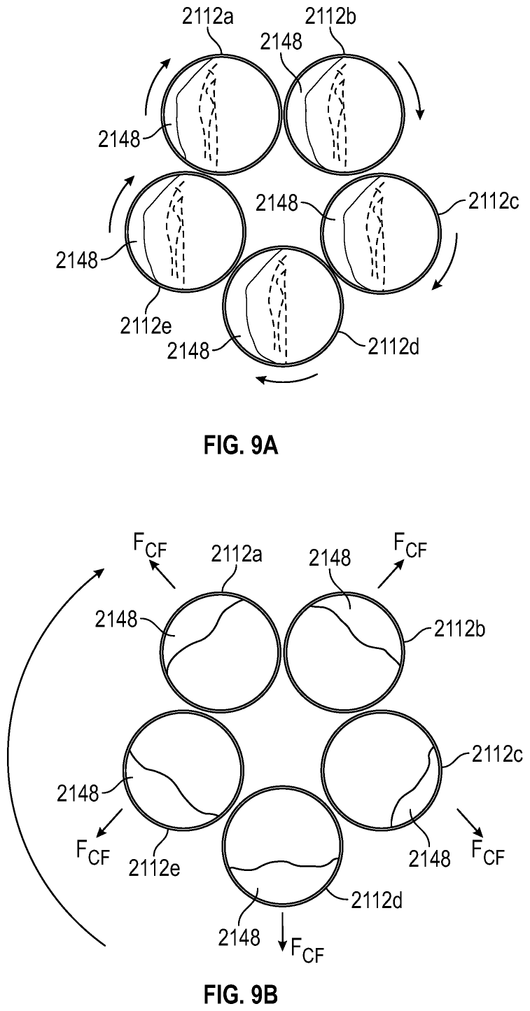

In another alternative embodiment, like the foregoing multi-vessel embodiment, multiple rotary treatment vessels 2112a-e are employed inside of a common stationary vacuum chamber. In this embodiment, however, as shown in FIG. 9A, the five rotary treatment vessels 2112a-e spin individually (planetary rotation) at a cataracting speed (ω₁), but spin in unison as shown in FIG. 9B at a centrifugal speed (ω₂). Rather than forming a toroid, in this embodiment the particles 2148 will, upon rotation at a centrifugal speed, collect against a portion of the inner surface of each rotary treatment vessel 2112a-e.

It should be understood that while the exemplary embodiments shown in FIGS. 8A-9B illustrate five rotary treatment vessels, it is contemplated that any number (e.g., 2, 3, 4, 5, 6, 7, 8, 9, 10, or more) of rotary treatment vessels may be provided within the common stationary vacuum chamber to process multiple batches of powder simultaneously.

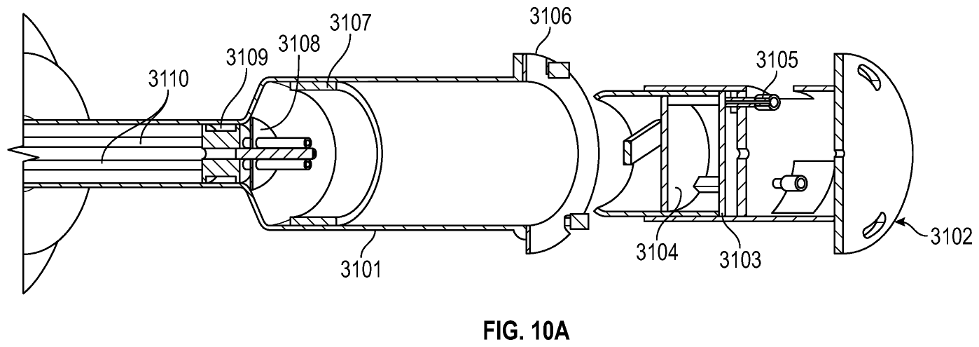

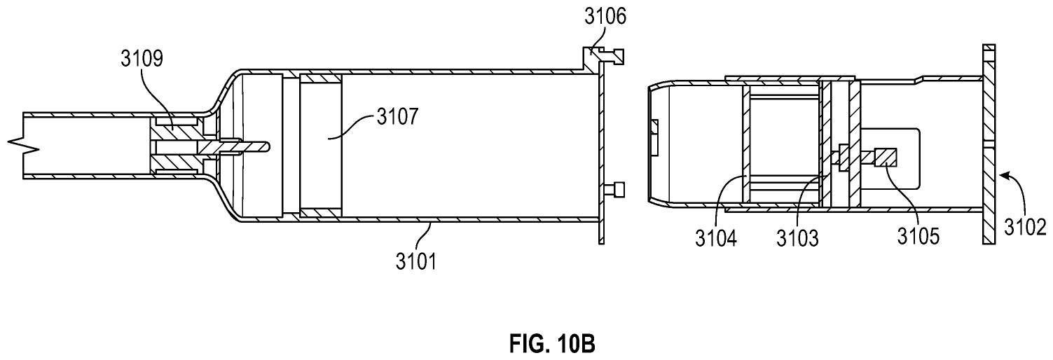

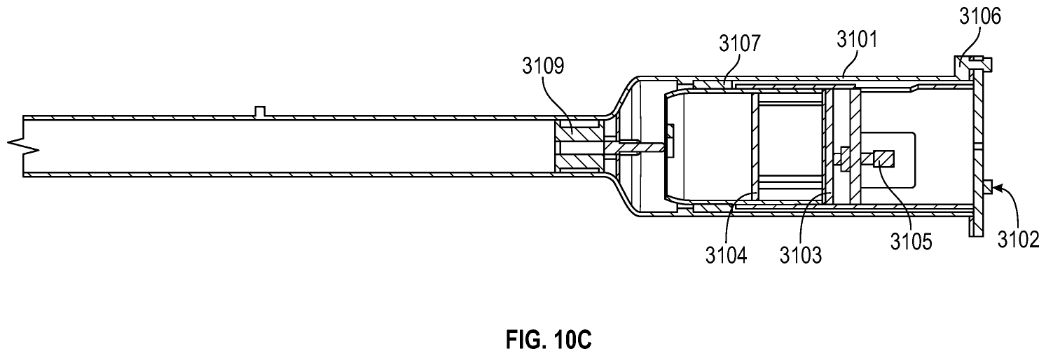

FIGS. 10A-10C show yet another construction of an illustrative powder treatment system in accordance with the present disclosure. The powder treatment system of FIGS. 10A-10C may be similar to and include any of the features of the powder treatment systems previously described herein, except as explicitly contradicted below. As such, only differences between the powder treatment system of FIGS. 10A-10C and the powder treatment systems previously described herein are set forth in detail below while similarities are summarily described or omitted entirely.

As seen in FIG. 10A, the powder treatment system includes a rotating process tube 3101 and a powder container 3102 that creates a sealed volume to contain the powder between two porous quartz plates, 3103 and 3104. The porosity of plates 3103 and 3104 is chosen to make them permeable for the process and purge gas but do not allow the powder particles to propagate through the plates. Plate 3104 is permanently welded to the quartz tube forming the powder container 3102, whereas plate 3103 is sealed to the flange 3106 of the powder container with locking screws 3105.

During the assembly powder container 3102 is inserted into process tube 3101 and locked with locking pins 3103 and a cushion 3107. Gasket 3108 and support part 3109 support non-rotating gas injector lines 3110 and help to contain the process gas inside of the rotating process tube 3101 before it propagates through the porous plates 3103 and 3104.

The disclosed structures can include any suitable mechanical, electrical, and/or chemical components for operating the disclosed powder treatment system or components thereof. For instance, such electrical components can include, for example, any suitable electrical and/or electromechanical, and/or electrochemical circuitry, which may include or be coupled to one or more printed circuit boards. As used herein, the term “controller” includes “processor,” “digital processing device” and like terms, and are used to indicate a microprocessor or central processing unit (CPU). The CPU is the electronic circuitry within a computer that carries out the instructions of a computer program by performing the basic arithmetic, logical, control and input/output (I/O) operations specified by the instructions, and by way of non-limiting examples, include server computers. In some aspects, the controller includes an operating system configured to perform executable instructions. Those of skill in the art will recognize that suitable server operating systems include, by way of non-limiting examples, FreeBSD, OpenBSD, NetBSD®, Linux, Apple® Mac OS X Server®, Oracle® Solaris®, Windows Server®, and Novell® NetWare®. In some aspects, the operating system is provided by cloud computing.

In one aspect of the present disclosure, the disclosed algorithms may be trained using supervised learning. Supervised learning is the machine learning (ML) task of learning a function that maps an input to an output based on example input-output pairs. The ML model infers a function from labeled training data consisting of a set of training examples. In supervised learning, each example is a pair including an input object (typically a vector) and a desired output value (also called the supervisory signal). A supervised learning algorithm analyzes the training data and produces an inferred function, which may be used for mapping new examples. In various embodiments, the algorithm may correctly determine the class labels for unseen instances. This requires the learning algorithm to generalize from the training data to unseen situations in a “reasonable” way.

In various embodiments, the present system may include a neural network that may be trained using training data, which may include, for example, different powder and/or treatment characteristics (e.g., powder composition, particle size, powder batch size, coating process, coating composition, etc.). The algorithm may analyze this training data and produce an inferred function that may allow the algorithm to identify powder agglomeration or treatment failure, based on the generalizations the algorithm has developed from the training data. In various embodiments, training may include at least one of supervised training, unsupervised training, and/or reinforcement learning.

In some aspects, a user can initiate a training session while watching operation to simplify setup on each unique powder and processing conditions. When the powder is deemed to be adequately treated, the user can open a training window which will then be used to calibrate or train the analytics for future anomaly detection. For instance, Linux®, which may run a Python® script, for example, may be utilized to effectuate prediction. In aspects, analytics may also be performed in the sensor using platforms such as Tensor Flow® lite.

In various embodiments, the neural network may include, for example, a three-layer temporal convolutional network with residual connections, where each layer may include three parallel convolutions, where the number of kernels and dilations increase from bottom to top, and where the number of convolutional filters increases from bottom to top. It is contemplated that a higher or lower number of layers may be used. It is contemplated that a higher or lower number of kernels and dilations may also be used.

This written description uses examples to describe the present powder treatment system and processes, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules associated with a particle treatment system.

In one or more examples, the described techniques may be implemented in hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media (e.g., RAM, ROM, EEPROM, flash memory, or any other medium that may be used to store desired program code in the form of instructions or data structures and that may be accessed by a computer).

Instructions may be executed by one or more processors, such as one or more digital signal processors (DSPs), general purpose microprocessors, application specific integrated circuits (ASICs), field programmable gate arrays (FPGAs), or other equivalent integrated or discrete logic circuitry. Accordingly, the term “processor” as used herein may refer to any of the foregoing structure or any other physical structure suitable for implementation of the described techniques. Also, the techniques could be fully implemented in one or more circuits or logic elements.

1. A system for treating fine powder particles comprising:
a rotary treatment vessel configured to expose a plurality of particles to treatment gases or vapors;
a controller configured to rotate the rotary treatment vessel at a first rotation speed to establish a cataracting condition, and at a second rotation speed to establish a centrifuging condition; and
a comb movable from a first position while the rotary treatment vessel is rotated at the first rotation speed, to a second position while the rotary treatment vessel is rotated at the second rotation speed.

2. The system according to claim 1 wherein the comb rotates from the first position to the second position.

3. The system according to claim 1 wherein the comb translates longitudinally in a direction parallel to a longitudinal axis of the rotary treatment vessel from the first position to the second position.

4. The system according to claim 1 wherein the first rotation speed is less than 100 RPM.

5. The system according to claim 1 wherein the second rotation speed is greater than 15 RPM.

6. The system according to claim 1 further comprising:
one or more gas injectors configured to intermittently introduce treatment gases or vapors into the rotary treatment vessel while the rotary treatment vessel rotates at the first rotation speed.

7. The system according to claim 6 wherein the one or more gas injectors are configured to uniformly raise a pressure inside the rotary treatment vessel.

8. The system according to claim 1 further comprising:
a vacuum port with an isolation valve to intermittently exhaust treatment gases or vapors from the rotary treatment vessel while the rotary treatment vessel rotates at the second rotation speed.

9. The system according to claim 1 wherein the comb includes rake-shaped tines configured to break up agglomerates formed by the plurality of particles, movement of the comb to the first position placing the tines into contact with at least a portion of the plurality of particles, and movement of the comb to the second position placing the tines out of contact with the plurality of particles.

10. The system according to claim 1 wherein the rotary treatment vessel is mounted horizontally.

11. The system according to claim 1 comprising a plurality of radially arrayed rotary treatment vessels, wherein the controller rotates the plurality of rotary treatment vessels at the second rotation speed around a common axis of rotation.

12. The system according to claim 11 wherein each rotary treatment vessel of the plurality of rotary treatment vessels defines a longitudinal axis, and the controller rotates each rotary treatment vessel of the plurality of rotary treatment vessels at the first rotation speed around its respective longitudinal axis.

13. A method for treating fine powder particles comprising:
loading particles into a rotary treatment vessel;
evacuating gas from the rotary treatment vessel while the rotary treatment vessel rotates at a centrifugal speed; and
introducing treatment gas or vapor into the rotary treatment vessel while the rotary treatment vessel rotates at a cataracting speed; and
while the rotary treatment vessel rotates at the cataracting speed, moving a comb to a first position into contact with a toroid of particles formed while the rotary treatment vessel rotates at the centrifugal speed.

14. The method according to claim 13 wherein loading particles into the rotary treatment vessel comprises loading Geldart group C powder into the rotary treatment vessel.

15. (canceled)

16. The method according to claim 13 further comprising mounting the rotary treatment vessel within a stationary vacuum chamber prior to rotating the rotary treatment vessel at either the cataracting speed or the centrifugal speed.

17. The method according to claim 13 wherein introducing treatment gas or vapor into the rotary treatment vessel results in deposition of a coating on the particles.

18. The method according to claim 13 wherein introducing treatment gas or vapor into the rotary treatment vessel is done under conditions that result in at least one of chemical vapor deposition, physical vapor deposition, plasma deposition, electrochemical deposition, molecular layer deposition, or atomic layer deposition.

19. A method for treating fine powder particles comprising:
loading particles into a rotary treatment vessel;
evacuating gas from the rotary treatment vessel while the rotary treatment vessel rotates at a centrifugal speed;
introducing treatment gas or vapor into the rotary treatment vessel while the rotary treatment vessel rotates at a cataracting speed; and
while the rotary treatment vessel rotates at the cataracting speed, moving a comb to a position into contact with cataracting particles.
